(19) United States
(12) Patent Application Publication
(10) Pub. No.: US 2026/0071516 A1
(43) Pub. Date: Mar. 12, 2026

(54) COMPUTER IMPLEMENTED METHOD FOR MULTISCALE ANALYSIS FOR DEFINING OIL WELL STABILITY WINDOWS AND COMPUTER READABLE NON-TRANSITIVE STORAGE MEDIA

(71) Applicants: Petróleo Brasileiro S.A. - Petrobras, Petróleo Brasileiro S.A. - Petrobras (BR); Faculdades Católicas - PUC-RIO, Rio de Janeiro (BR)

(72) Inventors: André Luís MULLER, Rio de Janeiro (BR); Juan Pablo IBAÑEZ, Rio de Janeiro (BR); Pedro Hugo Michelle Marie GHISLAIN CAMBIER, Rio de Janeiro (BR); Márcio SANTI, Rio de Janeiro (BR); Henrique SANTIAGO, Rio de Janeiro (BR); Flávio SZENBERG, Rio de Janeiro (BR)

(21) Appl. No.: 19/300,983

(22) Filed: Aug. 15, 2025

(30) Foreign Application Priority Data
Aug. 22, 2024 (BR) 10 2024 0171764

(51) Int. Cl. E21B 41/00; G06F 30/23

(52) U.S. Cl. CPC E21B 41/00; G06F 30/23; E21B 2200/20

(57) ABSTRACT

The present invention relates to a method for obtaining a stability window by applying multiscale numerical modeling (sedimentary basin-well) capable of estimating with greater accuracy the in-situ state used in well-scale analysis. Specifically, the present invention proposes modeling steps that treat the geomechanical analysis for well drilling projects as a multiscale analysis, with the possibility of including tectonic effects and physical couplings observed at larger scales (sedimentary basin, regional or lithospheric) in well-scale simulations. In general, the modeling is performed through the direct application of seismic data and the calculation of the overload to determine the parameters and boundary and initial conditions of the simulation, that is, without directly connecting the well-scale modeling with the larger geological context.

### CROSS-REFERENCE TO RELATED APPLICATION

This application claims priority to Brazilian Patent Application No. 10 2024 017176 4 filed on Aug. 22, 2024, the entirety of which is incorporated herein by reference.

### FIELD OF THE DISCLOSURE

The present invention is part of the technical field of oil and gas, more specifically, it is related to areas of geomechanical modeling being applied in any exploratory locations in the well drilling planning stage of the oil, natural gas and energy industry.

### BACKGROUND OF THE DISCLOSURE

The planning of the drilling of an oil well must answer some questions such as: what is the variation of the stress fields during and/or after the drilling process? What drilling pressure can be used to ensure that the well remains mechanically stable? In this context, the modeling of the stability window (range of variation of the internal pressure that ensures the stability of the well) is a fundamental step in the drilling design of a well and among the main factors that influence the analysis it can be mentioned the rheology of the geological environment, the diameter of the hole and the state of the in situ stresses before drilling.

In other words, efficient planning of the drilling of an oil well requires a meticulous approach and the consideration of several critical factors. Among the crucial questions that must be answered during this process, issues related to the variation of stress fields both during and after drilling stand out. It is essential to understand the dynamics of the stresses involved in order to ensure the mechanical stability of the well over time.

A central aspect of this planning is determining the appropriate drilling pressure that will ensure well stability. To this end, modeling the stability window plays a fundamental role in the drilling design. This window represents the range of internal pressure variation that is capable of maintaining the well in stable mechanical conditions, avoiding structural failures and operational problems.

Several factors influence the analysis of the stability window, and among them, the rheology of the geological environment assumes significant prominence. Understanding the rheological properties, which involve the deformation and flow behavior of the geological material, is crucial to determining the ideal drilling conditions. In addition, the hole diameter plays an important role, since it directly influences the pressures exerted on the well walls.

Another determining factor in modeling the stability window is the state of in situ pre-drilling stresses. Prior analysis of the stress conditions of the location where the well will be drilled is essential to anticipate and mitigate possible mechanical challenges that may arise during the drilling process.

Consequently, stability window modeling emerges as a critical step in planning the drilling of an oil well. By carefully considering the rheology of the geological environment, the borehole diameter and the in situ stress state, engineers can optimize drilling pressure, ensuring the mechanical stability of the well and contributing to the success of the oil venture.

However, knowledge of the in situ stress state before drilling is obtained indirectly and, in many cases, in a simplified manner, through the use of seismic data and the calculation of overload. Therefore, there is a need to refine this essential modeling data through integration with evolutionary numerical analysis at the basin scale, capable of aggregating information/processes not accounted for by traditional and current methods and, consequently, increasing the reliability of the stability window determination.

The present invention fits into the aforementioned context, offering an agile and automated solution for obtaining a stability window by applying a computer-implemented method that executes multiscale numerical modeling (sedimentary basin-well) capable of accurately estimating the in situ state used in the well-scale analysis.

Specifically, the present invention proposes a method that executes the geomechanical analysis for well drilling projects as a multiscale analysis, with the possibility of including tectonic effects and physical couplings observed at larger scales (sedimentary basin, regional or lithospheric) in the well-scale simulations. Since, in general, modeling is performed through the direct application of seismic data and the calculation of the overload to determine the parameters and boundary and initial conditions of the simulation, that is, without directly connecting the well-scale modeling with the larger geological context.

In view of this, and in order to solve the technical problems described above, with the present invention it is possible to observe technical advantages such as the reduction of uncertainties in the exploratory process, with the integration of the well stability analysis with the geomechanical analysis on a sedimentary basin scale, allowing to obtain geologically more robust and accurate results for the evaluation of the well trajectory, with an agile and integrated method of well stability modeling using the results of the analysis on a basin scale, in addition to allowing to considerably reduce the time spent on the construction of well cutting models, implying in the increase in the productivity of geoscientists specialized in this activity, in addition, greater efficiency in the evaluation of exploratory prospects, with the reduction of the modeling time that also directly impacts the response time of the evaluation of exploratory prospects.

In the state of the art, there are models that are performed through the direct application of seismic data and the calculation of the overload to determine the parameters and boundary and initial conditions of the simulation, that is, without directly connecting the well-scale modeling with the larger geological context, presenting deficiencies when compared with the method of the present invention, since in general terms no method in the state of the art shows a modeling flow that treats the geomechanical analysis for well drilling projects with a multiscale analysis, with the possibility of including tectonic effects and physical couplings observed on larger scales (sedimentary basin, regional or lithospheric) in the well-scale simulations.

The patent document US20160349389 A1, for example, relates to a model of geomechanical properties in an underground volume including an oil and/or gas reservoir obtained using seismic data acquired with sensors placed to probe the underground reservoir, well logs drilled within the underground volume and information on the horizontal, deviated and vertical drilling cuttings composition of the wells. The composition information is used to calibrate the well logs, which are then used to improve the models obtained from the seismic data.

However, the document US20160349389 A1, unlike the present t invention, performs multiple multivariate analysis based on the well logs and the inversion solution. Seismic attributes (e.g. amplitude, compressional and shear velocities, density and its derivatives, product, etc.) are used to estimate log and reservoir properties away from wells using a statistical methodology that trains a set of seismic attributes to predict reservoir properties using multi-transformations of linear and neural networks.

In its turn, the document U.S. Pat. No. 10,920,552 B2 applies to a method for performing oilfield operations at a well site. The well site is positioned around an underground formation having a wellbore through it and a network of fractures therein. The network of fractures includes natural fractures. The method involves generating fracture parameters including a hydraulic fracture network based on well site data including an earth mechanical model, generating reservoir parameters including a reservoir grid based on the well site data and the generated fracture well site parameters, generating production parameters comprising the production rate over time based on the well site data and the hydraulic fracture network, forming a finite element grid from the fracture parameters, the production parameters and the reservoir parameters, coupling the hydraulic fracture network to the reservoir grid, generating integrated geomechanical parameters including estimated microseismic events based on the finite element grid and performing fracture operations and production operations based on the integrated geomechanical parameters.

However, the present invention differs from the document U.S. Pat. No. 10,920,552 B2 in that it shows a finite element mesh model that solves the equations generated in the previous steps of the methodology.

The document U.S. Pat. No. 11,009,620 B2 describes a method for determining a favorable time window of an infill well of an unconventional oil and gas reservoir, which comprises the following steps: S1, establishing a three-dimensional geological model with physical properties and geomechanical parameters; S2, establishing a natural fracture network model in combination with internal logging seismic monitoring; S3, calculating complex fractures in hydraulic fracturing of parent wells; S4, establishing an unconventional oil and gas reservoir model and calculating a current pore pressure field; S5, establishing a dynamic geomechanical model and calculating a dynamic geostress field; S6, calculating complex fractures in horizontal fractures of the infill well at different production times of the parent wells based on pre-stage complex fractures and the current geostress field; S7, analyzing a barrier region of microseismic events and its dynamic changes in fracturing of infill wells; and S8, analyzing the productivity at different filling times, and determining a filling time window.

The present invention differs from document U.S. Pat. No. 11,009,620 B2, as it does not show a step S5, which establishes a four-dimensional dynamic geostress model with physical properties of the reservoir and mechanical properties of the rock using the three-dimensional geological model and analyzing and calculating the dynamic evolution of the reservoir geostress according to the results of the change of the pore pressure field.

Regarding the document CN 116842789 A, it describes a method of analyzing the stability of an encrypted well wall considering a production time window, which adopts the technical scheme that: loads a preliminary well track into a three-dimensional geomechanical model of a reservoir; secondly, carries out numerical simulation of the hydraulic fracture of the parent well to obtain a real expansion form of the hydraulic fracture; then simulates stratum pressure parameters under different production time conditions, and performs inversion correction on the stratum pressure parameters through history adjustment; acquires a core of a target reservoir, obtains the change rules of corresponding mechanical parameters under different pore pressure conditions through experiments, and constructs a rock mechanical parameter change equation under different pore pressure conditions; finally, the encryption well track is fed into a dynamic geomechanical field model, and the design of the encryption well drilling scheme is guided according to the optimized safe drilling mud window. The invention can improve the stability of the wellbore wall of the encrypted well, thereby reducing the occurrence of well drilling accidents, improving the drilling efficiency of the encrypted well, and ensuring the successful completion of the subsequent encrypted well fracturing reform.

The present invention, unlike CN 116842789 A, seeks to determine what drilling pressure should be applied to the wellbore wall to ensure the stability conditions of the well, based only on two criteria, the shear and the traction criteria.

### SUMMARY OF THE DISCLOSURE

The present invention relates to a computer-implemented method for multiscale analysis to define stability windows of oil wells, comprising the steps of: (a) performing a geomechanical analysis on a basin-scale model; (b) performing an evaluation of a wellbore stability window on a model derived/extracted from step (a); and (c) obtaining a drilling pressure that should be applied to the wall of a well to ensure the stability conditions of the well. In the basin-scale model of step (a), an arbitrary point marking the well trajectory serves as a reference to start step (b). In step (a), a stress analysis considering different physical behaviors, such as purely mechanical, fluid-mechanical or thermo-fluid-mechanical, is performed. In the basin-scale model resulting from step (a), the tectonic effects are modeled as a function of the types of loads, initial conditions in terms of stresses or displacements, temperatures or pore pressures, previously applied to the basin-scale model as boundary conditions. Furthermore, step (a) comprises: (a.1) creating a geometric model, on a basin scale, representing a geological context wherein a well is inserted; (a.2) assigning to the model geomechanical properties and boundary conditions characteristic of a given geological context; (a.3) discretizing the model through a finite element mesh; and (a.4) performing a geomechanical numerical analysis to obtain results in terms of stress and deformation. In step (a.2) the geomechanical properties comprise a definition of the rheological behavior (stress×deformation) of the materials, initial and boundary conditions of the given geological context. In step (a.2) the materials comprise an elastic type comprising elastic/reversible deformations, an elastoplastic type comprising elastic/reversible and plastic/permanent deformations, or a viscoelastic type, comprising elastic/reversible and viscous deformations. In addition, step (b) comprises: creation of the geometric model and assignment of geomechanical properties and boundary conditions via template (extracted from the basin-scale model), complemented with geometric data from the wellbore such as diameter, azimuth and inclination; (b.2) discretization through a finite element mesh automatically; (b.3) execution of a mathematical optimization process (applied to well-scale geomechanical analysis) using the Accelerated Newton-Raphson method or the Aitken Accelerated False Position Method and the constraints of equations [48], and to obtain the stability window for the internal pressure of the wellbore; (b.4) presenting the final result in a graph representing the well trajectory with an indication of the stability window obtained.

The present invention also relates to a non-transitory computer-readable storage medium comprising instructions stored therein, wherein the instructions, when read by a computer, cause the computer to execute the steps of the method as defined above.

### BRIEF DESCRIPTION OF THE FIGURES

In order to complement the present description and obtain a better understanding of the characteristics of the present invention, and in accordance with a preferred embodiment thereof, a set of figures is attached, where in an exemplary, although not limitative, manner its preferred embodiment is represented.

FIG. 1 represents a model geometry of the claimed method comprising: stratigraphic horizons, faults, layers and well trajectories, in accordance with a preferred embodiment of the present invention.

FIG. 2 is a representation of step (a.2) of the requested method, in which the assignment of geomechanical properties to the geometric model created in step (a.1) is performed, the geomechanical properties comprising: definition of the rheological behavior, that is, that which governs the relationship between stress and deformation of the materials (which may be of the elastic type, characterized by elastic/reversible deformations, elastoplastic characterized by elastic/reversible and plastic/permanent deformations, or viscoelastic, characterized by elastic/reversible and viscous deformations), initial and boundary conditions of the problem, according to a preferred embodiment of the present invention.

FIG. 3 represents step (a.3) of the requested method, of creating the finite element mesh of the requested method, according to a preferred embodiment of the present invention.

FIG. 4 illustrates the representation of step (a.5) for displaying the results of the stress field of the basin-scale simulation and, in detail, this result expressed graphically along the well path traced in the original model and the marking of an arbitrary point on the well path that will serve as a reference to start step (b) of the requested method, according to a preferred embodiment of the present invention.

FIG. 5 is a representation of a numerical model generated from the information of the requested method comprising: geometry the well of section, boundary conditions and rheological behavior extracted directly from the basin-scale model and automatically assigned from step (b.1), as well as the finite element mesh created in step (b.2), according to a preferred embodiment of the present invention.

FIG. 6 illustrates the intended representation of the result of the numerical modeling at the end of the well-scale simulation for stability window analysis of step (b.4). The graph represents the profile of a well, whose trajectory is defined in the basin-scale model of FIG. 1, in which the pore pressure, total vertical stress and minimum total horizontal stress curves obtained from the basin-scale model are plotted and which serve as graphical references for the analysis of the results of the stability window; and the stability analysis performed on a well scale, carried out at an arbitrary depth and represented by a horizontal line, wherein the circles represent the minimum and maximum breakout limits, with the interval between the two limits (represented with a solid line) marking the safety interval of the window, while the interval beyond the limits (represented with a dashed line) indicates that in this section the stability requirements for the pressure window were not met, in accordance with a preferred embodiment of the present invention.

FIG. 7 is a summarized representation of the flowchart of the method of the present invention comprising the steps (a)-basin-scale simulation, (a.1)-geometric model, (a.2)-geomechanical attributes and boundary conditions, (a.3)-finite element mesh, (a.4)-geomechanical simulation, (a.5)-results (stress and strain fields), (b)-well-scale simulation, (b.1)-automatic creation of the well section model with geomechanical attributes and boundary conditions extracted from the model and results in (a) and geometric data defined through a template, (b.2)-finite element mesh, (b.3)-optimization process/calculation of stability window and (b.4)-graphs of results indicated in the well trajectory.

### DETAILED DESCRIPTION OF THE DISCLOSURE

The present invention relates to a computer-implemented method for multiscale analysis applied to the definition of stability windows of oil wells. Specifically, the multiscale analysis flow applied to obtain stability windows for oil wells aims to inform a pressure range (window) for drilling an oil well without it presenting instabilities due to high mechanical damage in the surroundings of the well.

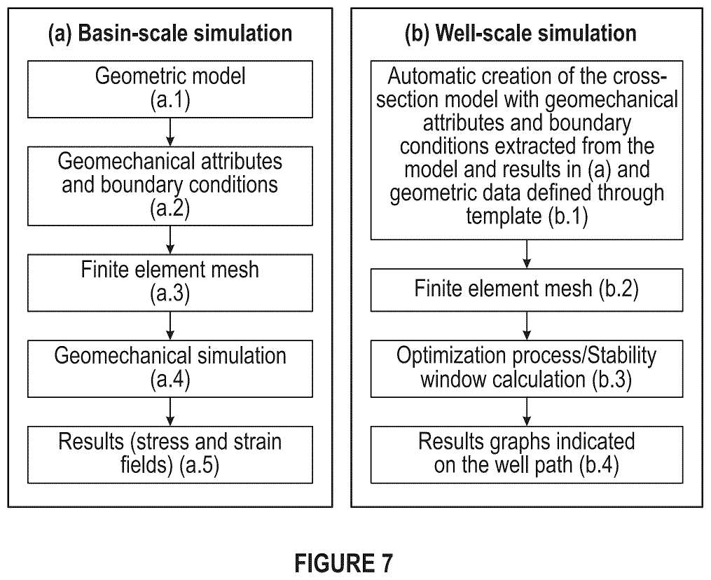

Specifically, as seen in FIG. 7, the present invention relates to a computer-implemented method for multiscale analysis for defining stability windows of oil wells, comprising the steps of: (a) performing a geomechanical analysis on a basin-scale model; (b) performing an evaluation of a well stability window on a model derived/extracted from step (a); and (c) obtaining a drilling pressure that must be applied to the wall of a well to ensure the stability conditions of the well. In the basin-scale model of step (a) an arbitrary point marking on the well trajectory serves as a reference to start step (b). In step (a) a stress analysis considering different physical behaviors, such as purely mechanical, fluid-mechanical or thermo-fluid-mechanical, is performed. In the basin-scale model resulting from step (a), tectonic effects are modeled according to the types of loads, initial conditions in terms of stresses or displacements, temperatures or pore pressures, previously applied to the basin-scale model as boundary conditions. Furthermore, step (a) comprises: (a.1) creating a geometric model, on a basin scale, representing a geological context in which a well is inserted; (a.2) assigning to the model geomechanical properties and boundary conditions characteristic of a given geological context; (a.3) discretizing the model through a finite element mesh; and (a.4) performing a geomechanical numerical analysis to obtain results in terms of stress and deformation. In step (a.2) the geomechanical properties comprise a definition of the rheological behavior (stress×deformation) of the materials, initial conditions and boundary conditions of the given geological context. In step (a.2) the materials comprise an elastic type comprising elastic/reversible deformations, an elastoplastic type comprising elastic/reversible and plastic/permanent deformations, or a viscoelastic type, comprising elastic/reversible and viscous deformations. In addition, step (b) comprises: creation of the geometric model and assignment of geomechanical properties and boundary conditions via template (extracted from the basin-scale model), complemented with geometric data from the wellbore such as diameter, azimuth and inclination; (b.2) discretization through a finite element mesh automatically; (b.3) execution of a mathematical optimization process (applied to well-scale geomechanical analysis) using the Accelerated Newton-Raphson method or the Aitken Accelerated False Position Method and the constraints of equations [48], [49] and [50] to obtain the stability window for the internal pressure of the wellbore; (b.4) presenting the final result in a graph representing the well trajectory, indicating the stability window obtained.

The present invention relates to a computer-implemented method for multiscale analysis applied to the definition of stability windows for oil wells. Specifically, the multiscale analysis flow applied to obtain stability windows for oil wells is constructed by a set of numerical procedures, optimization methods, data structures and graphical interfaces and aims to inform a pressure range (window) for drilling an oil well without it presenting instabilities due to high mechanical damage in the surroundings of the well.

In general, well instabilities are caused by geomechanical imbalances which, in its turn, are caused by disturbances in the balanced condition of the porous medium where the well will be drilled. In order to define the level of disturbance in the balanced condition, prior to the drilling event, it is necessary to know the stress levels acting on the porous medium. Therefore, the first step in the multiscale analysis flow is the basin-scale analysis. To perform the geomechanical analysis on a basin-scale model (a), a stress analysis is performed with the possibility of considering different physical behaviors: purely mechanical, fluid-mechanical or thermo-fluid-mechanical.

Initially, in step (a.1) a geometric model is created, on a basin l scale, representing the geological context in which the well is inserted.

Still in step (a), for the purely mechanical definitions, the continuous medium with domain Ω⊂R³, contour Γ in a time interval tϵ[0, T] is considered. Fundamentally, to analyze a deformable continuous medium, the aim is to guarantee the conditions of continuity, conservation of mass, and movement. The continuity equation of a solid phase can be expressed by:

$$\frac{d}{dt} ( \text{?} ) + div ( \text{?} ) = 0 \qquad ( 1 )$$

$$\text{?} \text{indicates text missing or illegible when filed}$$

In the continuity equation, ρₛ and vₛ represent, respectively, the density and velocity vector of the solid phase. The symbol div represents the divergence operator. The equation of motion can be described by conservation of momentum, given by:

$$ρ \text{?} \frac{d}{dt} ( \text{?} ) - div ( σ ) - ρ \text{?} g = 0 \qquad ( 2 )$$

$$\text{?} \text{indicates text missing or illegible when filed}$$

In the equation above, σ represents the Cauchy stress tensor and g the gravitational acceleration. When considering the static equilibrium condition of the medium, it is assumed that

$$\frac{d}{dt} ( \text{?} ) = 0 ,$$

$$\text{?} \text{indicates text missing or illegible when filed}$$

therefore, conservation of momentum can be described by:

$$div ( σ ) + ρ \text{?} g = 0 \qquad ( 3 )$$

$$\text{?} \text{indicates text missing or illegible when filed}$$

In order to solve the problem, it is also necessary to define and treat the initial conditions and boundary conditions appropriately. In general, the initial conditions specify initial stress and displacement fields u at time t=0.

$$u = \text{?} u , σ = \text{?} σ em Ω e Γ \qquad ( 4 )$$

$$\text{?} \text{indicates text missing or illegible when filed}$$

In step (a.2), in which the model must be assigned geomechanical properties and boundary conditions characteristic of the geological context, the boundary conditions are in its turn specified in terms of displacements and boundary loads. In this case, for a boundary Γ there is:

$$u {=}_{u}^{Γ} e {I}_{σ}^{T} = t \qquad ( 5 )$$

I is a matrix related to the normal unit vectors n={nₓ n_{y} n_{z}}^{T} and t the boundary loads.

Finally, adding the boundary condition in terms of loads on the boundary to the momentum continuity equation and integrating these equations, respectively in the domain and on the boundary, there is the differential equation that deals with problems in deformable continuous media according to a classical approach. To assume a more simplified representation, the portion of body forces is described as ρ,g=b, thus:

$${\int }_{Ω} div ( σ ) + bd Ω + {\int }_{r} {I}_{σ}^{T} - td Γ = 0 \qquad ( 6 )$$

In this invention, to deal with the mechanical behavior of the porous medium, it is possible to adopt a non-classical approach, described by generalized Cosserat mechanics. In the generalized Cosserat approach, the momentum continuity equation is described in a similar way to that presented in the classical approach. However, some additional terms related to microrotations and moment stresses, among others, are included in this approach. As previously mentioned, the main difference between the classical approach and the Cosserat approach is the kinematics of material points. In the Cosserat continuum, particles, considered as small continua, exhibit rigid behavior and free rotations. The movements in addition to the traditional displacements of the classical approach are microrotations. Thus, the kinematics are enriched by the gradient of microrotations and curvatures. In the Cosserat continuum, the gradient of microrotations is combined with moment stresses, quantities not observed in the classical continuum. Moment stresses have the dimension of moment per area. Displacement gradients are combined with stresses as in the classical continuum, however, now the tensor will not present symmetry. With this kinematic enrichment, it is possible to contemplate bending and torsion effects in the medium. Thus, a new macroscopic stress tensor is described, Cosserat stresses, σ^{c}, which is different from the Cauchy tensor because it shows asymmetry.

$$\text{?} = σ + \text{?} \qquad ( 7 )$$

$$\text{?} \text{indicates text missing or illegible when filed}$$

ι is the relative stress tensor.

Among the distinctions between the classical approach and the Cosserat approach is the fact that the latter has in its constitutive description the intrinsic presence of a characteristic length. This length represents the dimension of the particle. Thus, if this dimension is considered extremely small, the Cosserat continuum degenerates into a classical continuum.

In the Cosserat continuum, the displacement gradients and the microdisplacement gradients are independent. Thus, it is possible to subdivide the description of the momentum continuity into two parts.

$$div ( \text{?} ) + b = 0 \qquad ( 8 )$$

$$div ( \text{?} + \text{?} ) + \text{?} = 0 \qquad ( 9 )$$

$$\text{?} \text{indicates text missing or illegible when filed}$$

μ is a third-order tensor called the double stress tensor.

In equation 9, only the asymmetric parts are considered. The asymmetric part of the Cosserat tensor a ^{a}σ^{c} is given solely by the asymmetric part of the relative stresses. Θ is interpreted as mass moment.

In a similar way to that shown in the classical approach, initial boundary and conditions must be established. In a Cosserat continuum, the initial conditions specify initial fields of stresses, displacements uₑ microrotations ω at time t=0. The boundary conditions, in its turn, are specified in terms of displacements, microrotations and boundary loads. In this case, for a boundary Γ there is:

$$u {=}_{u}^{Γ} , ω {=}_{ω}^{Γ} , \text{?} μ = τ \qquad ( 10 )$$

$$\text{?} \text{indicates text missing or illegible when filed}$$

Thus, the non-classical boundary conditions are given in terms of microrotations in the boundary. Using the permutation tensor eᵢⱼₖ and it can be written:

$$\text{?} = \frac{1}{2} \text{?} \qquad ( 11 )$$

$$\text{?} = \frac{1}{2} \text{?} \qquad ( 12 )$$

$$\text{?} = \frac{1}{2} \text{?} \qquad ( 13 )$$

$$\text{?} \text{indicates text missing or illegible when filed}$$

In the equations above cu represents the moment stress tensor. Finally, the conservation of momentum for the Cosserat approach can be written as follows:

$${\int }_{Ω} div ( \text{?} ) + b + Θ d Ω + \int \text{?} - t + \text{?} - τ d Γ = 0 \qquad ( 14 )$$

$$\text{?} \text{indicates text missing or illegible when filed}$$

In order to consider the behavior arising from fluid-mechanical effects in the porous medium, it is first necessary to define a physical model. The definition of the physical model begins with the presentation of the concepts of volumetric mean and intrinsic volumetric mean. These concepts are useful given the difficulty of describing problems at the microscopic level. A representative elementary volume (VER) of total volume

$$V = {\sum }_{f} {V}_{f}$$

is used to define the volumetric mean. V_{f} is the volume occupied by a phase f. The volumetric average of a quantity χ for a phase f is given by:

$$〈 \text{?} 〉 = \frac{1}{V} \int \text{?} dV \qquad ( 15 )$$

$$\text{?} \text{indicates text missing or illegible when filed}$$

and the intrinsic volumetric average is given by

$$\text{?} \qquad ( 16 )$$

$$\text{?} \text{indicates text missing or illegible when filed}$$

Where L is a characteristic length associated with the porous medium on a macroscopic scale, d is a length associated with the pores and l is the characteristic length of the VER. With this relationship satisfied, it is also expected that the volumetric average is independent of time and position in the porous medium.

In general, the voids of the porous medium are filled with fluids and a mixture of air (water vapor, gas, etc.). Considering the hypothesis that the porous medium is completely filled with two fluid phases (wetting phase w and non-wetting phase nw), the degree of saturation of a phase f is given by the ratio between the volume of pores occupied by the fluid f, V_{f} and the total volume of pores of a representative elementary volume, Vᵣ.

$${S}_{f} = \frac{V \text{?}}{V \text{?}} \qquad ( 17 )$$

$$\text{?} \text{indicates text missing or illegible when filed}$$

where Vᵣ=V_{w}+V_{nw}. Thus S_{w}+S_{nw}=1. Where S_{w} is the degree of saturation of the wetting phase and S_{nw} is the degree of saturation of the non-wetting phase.

The porosity of the medium is defined by the ratio between the total pore volume and the total VER volume.

$$ϕ = \frac{\text{?}}{V} \qquad ( 18 )$$

$$\text{?} \text{indicates text missing or illegible when filed}$$

The definition of the physical model continues by describing the stresses. It is assumed: positive traction, in the solid phase σₛ and positive compression for pore pressure in the fluid phase σ_{f}. By applying the concept of intrinsic volumetric average, the average total stresses can be obtained, that is

$$\begin{matrix}〈 σ 〉 = \frac{1}{V} {\int }_{\text{?}} σ dV = \frac{1}{V} ( {\int }_{\text{?}} σ dV + {\int }_{{V}_{\text{?}}} σ dV ) \\ 〈 σ 〉 = \frac{{V}_{\text{?}}}{V} {〈 {σ}_{\text{?}} 〉}^{\text{?}} + \frac{{V}_{f}}{V} ( \frac{{V}_{\text{?}}}{{V}_{f}} {〈 {σ}_{\text{?}} 〉}^{\text{?}} + \frac{{V}_{\text{?}}}{{V}_{f}} {〈 {σ}_{\text{?}} 〉}^{\text{?}} ) \\ 〈 {σ}^{\text{?}} 〉 = ( 1 - ϕ ) {〈 {σ}_{\text{?}} 〉}^{\text{?}} + ϕ ( {S}_{\text{?}} {〈 {σ}_{\text{?}} 〉}^{\text{?}} + {S}_{\text{?}} {〈 {σ}_{\text{?}} 〉}^{\text{?}} )\end{matrix} \qquad ( 19 )$$

$$\text{?} \text{indicates text missing or illegible when filed}$$

σ_{π} represents the average stress tensor of the phase f.

For the fluid phase, the stress tensor is expressed according to (3.7)

$${σ}_{f} = {τ}_{f} - {mp}_{f} \qquad ( 20 )$$

where τ_{f} represents the shear stresses and m is a vector containing values equal to 1 for normal stresses and 0 for the shear stress components.

$$m = {\{ \begin{matrix}1 & 1 & 1 & 0 & 0 & 0\end{matrix} \}}^{\text{?}} \qquad ( 21 )$$

$$\text{?} \text{indicates text missing or illegible when filed}$$

Neglecting the portion related to shear stresses for fluids, it can be written

$$〈 {σ}^{\text{?}} 〉 = ( 1 - ϕ ) {〈 {σ}_{\text{?}} 〉}^{\text{?}} + ϕ m ( {S}_{\text{?}} {〈 {p}_{\text{?}} 〉}^{\text{?}} + {S}_{\text{?}} {〈 {p}_{\text{?}} 〉}^{\text{?}} ) \qquad ( 22 )$$

$$or even :$$

$$\begin{matrix}〈 {σ}^{\text{?}} 〉 = ( 1 - ϕ ) {〈 {σ}_{\text{?}} 〉}^{\text{?}} + ϕ m {〈 {p}^{f} 〉}^{f} \\ {〈 {p}^{f} 〉}^{f} = {S}_{\text{?}} {〈 {p}_{\text{?}} 〉}^{\text{?}} + {S}_{\text{?}} {〈 {p}_{\text{?}} 〉}^{\text{?}}\end{matrix} \qquad ( 23 )$$

$$\text{?} \text{indicates text missing or illegible when filed}$$

where [symbol] p^{t} [symbol] ^{t} is the average pore pressure from the wetting and non-wetting phases.

It is verified that the stress tensor is divided into two components: one that represents the effect of pore pressures and another that deforms the solid skeleton, effective stresses σ′.

$$〈 {σ}^{\text{?}} 〉 = ( 1 - ϕ ) {〈 {σ}_{\text{?}} 〉}^{\text{?}} + m {〈 {p}^{f} 〉}^{f} \qquad ( 24 )$$

$$\text{?} \text{indicates text missing or illegible when filed}$$

By omitting the symbol [symbol] [symbol] and representing p^{f} only by p, the total stress tensor can be described by 3.12, and this representation is consistent with the definition of Terzaghi.

$$σ = {σ}^{\text{?}} - mp \qquad ( 25 )$$

$$\text{?} \text{indicates text missing or illegible when filed}$$

In addition, it is possible to use the concept of Biot, represented below by α, describing the total stresses as

$$σ = {σ}^{\text{?}} - α mp \qquad ( 26 )$$

$$\text{?} \text{indicates text missing or illegible when filed}$$

The effective stresses, therefore, are described as

$${σ}^{\text{?}} = D ( {ε}^{\text{?}} - {ε}^{\text{?}} - {ε}^{\text{?}} - {ε}^{\text{?}} ) + {σ}_{0}^{\text{?}} \qquad ( 27 )$$

$$\text{?} \text{indicates text missing or illegible when filed}$$

where D is the constitutive tensor that relates stresses and deformations, and which among other things describes whether the relationship is of a plane state of deformations or stresses, three-dimensional, etc. and ε^{t} represents the total deformations, and ε^{p} represents the plastic deformations, and ε^{v} defines the viscous deformations, and ε^{T} represents the deformations due to the temperature differential and σ′₀ represents the initial effective stresses.

In a porous medium, the fluid flow must satisfy the conservation of fluid mass. To perform the fluid mass balance, an elementary cube made of porous material is taken as the control volume. Taking initially the flow in the d_{y} direction through the dₓd_{z} face, the fluid mass flow is (ρq_{y})₁dₓd_{z} and (ρq_{y})₂dₓd_{z}. Where ρ and q are the fluid density and flow rate, respectively. Considering that (ρq_{y}) is a continuous and differentiable function, it is possible to write

$${( ρ {q}_{y} )}_{\text{?}} = {( ρ {q}_{y} )}_{\text{?}} + \frac{\partial ( ρ {q}_{y} )}{\partial y} {d}_{y} \qquad ( 28 )$$

$$\text{?} \text{indicates text missing or illegible when filed}$$

Thus, the flow in the y direction generates a decrease in the fluid mass equal to:

$${( ρ {q}_{\text{?}} )}_{\text{?}} - {( ρ {q}_{y} )}_{\text{?}} = \frac{\partial ( ρ {q}_{y} )}{\partial y} {d}_{y} \qquad ( 29 )$$

$$\text{?} \text{indicates text missing or illegible when filed}$$

Adopting the same procedure for the other directions and summing the three resulting parcels, the fluid mass balance due to the flow is obtained

$$( \frac{\partial ( ρ {q}_{x} )}{\partial x} + \frac{\partial ( ρ {q}_{y} )}{\partial y} + \frac{\partial ( ρ {q}_{z} )}{\partial z} ) {d}_{x} {d}_{y} {d}_{z} = {∇}^{γ} ( ρ q ) {d}_{x} {d}_{y} {d}_{z} \qquad ( 30 )$$

It is then possible to represent the fluid mass balance in the porous medium, the continuity equation

$${∇}^{γ} ( ρ q ) {d}_{x} {d}_{y} {d}_{z} + \frac{d}{d \text{?}} ( {m}_{\text{?}} {d}_{\text{?}} {d}_{y} {d}_{z} ) = 0 \qquad ( 31 )$$

$${∇}^{γ} ( ρ q ) + {\dot{m}}_{l} = 0 \qquad ( 32 )$$

$$\text{?} \text{indicates text missing or illegible when filed}$$

where \dot{m}_{f} represents the increase in fluid mass in an infinitesimal parcel of the porous medium per unit of time and ∇ is the differential operator.

A single fluid phase is assumed in the porous medium. With the law of Darcy, the velocity of a fluid in a porous medium is given by

$${v}_{f} = \frac{k}{{ϑ}_{f}} ∇ ( {p}_{f} + {ρ}_{f} gh ) \qquad ( 33 )$$

f represents the fluid, ρ_{f} represents the density of the fluid, k is the absolute permeability tensor of the porous medium, g the acceleration of gravity, h is the elevation load and σₜ the dynamic viscosity of the fluid f.

As previously described, in a porous medium, the fluid flow must satisfy the conservation of fluid mass.

It can be assumed that the porous medium can be described by two parts, one formed by interconnected pores that occupy a volume Vₚ, and another composed of isolated pores and solid particles, called Vₛ. The total volume of the porous medium V is given by the sum of each constituent part: V=Vₚ+Vₛ.

Assuming also that the porous medium is completely saturated, the volume of fluid V_{f} that can freely circulate through the pores is equal to the pore volume. The porosity φ is the ratio of the pore volume to the total volume: φ=Vₚ/V. It is possible to express the mass of fluid per unit volume as m_{f}=ρ_{f}φ. Thus, \dot{m}_{f}=\dot{φ}ρ_{f}+\dot{ρ}_{f}φ. The term \dot{φ}ρ_{f} represents the variation in the fluid mass associated with the increase in porosity, while the term represents the expansion of the fluid.

The variation in pore volume Vₚ can be decomposed into two parts, the first corresponding to the volumetric variation of the solid skeleton and the second corresponding to the variation in grain volume. The volumetric variation of the solid skeleton is given by:

$$\frac{dV}{V} = {dz}_{\text{?}} = {m}^{\text{?}} d ε \qquad ( 34 )$$

$$\text{?} \text{indicates text missing or illegible when filed}$$

While the variation in grain volume is obtained considering that the grains deform elastically and that the load applied for this deformation can be decomposed into two parts. The first part corresponding to the increase in effective stresses and the second corresponding to the increase in confining stresses, which in its turn generate an increase in pore pressures of equal magnitude. By adding these two components, the variation in grain volume is obtained

$$\frac{{dV}_{\text{?}}}{V} = {m}^{T} ( 1 - α ) d ϵ - [ \frac{( α - ϕ )}{{K}_{\text{?}}} + \frac{ϕ}{{K}_{f}} ] {dp}_{\text{?}} \qquad ( 35 )$$

$$\text{?} \text{indicates text missing or illegible when filed}$$

Thus, the variation in pore volume is obtained by

$$d ϕ = \frac{dV}{V} - \frac{dV \text{?}}{V} \text{?} \qquad ( 36 )$$

$$or :$$

$$\text{?} = [ \text{?} ] \text{?} + [ \frac{( α - ϕ )}{K \text{?}} + \frac{ϕ}{{K}_{j}} ] \text{?}$$

$$\text{?} \text{indicates text missing or illegible when filed}$$

The variation in fluid density is described by

$$ρ \text{?} = \frac{ρ \text{?}}{K \text{?}} ρ \text{?}$$

$$\text{?} \text{indicates text missing or illegible when filed}$$

where K_{f} is the volumetric modulus of the fluid. With the definitions previously indicated, it is possible to define \dot{m}_{π} and finally, considering that the density of the fluid over time is constant, the following is written:

$$[ α m \text{?} ] \text{?} [ \frac{( α - ϕ )}{K \text{?}} + \frac{ϕ}{K \text{?}} ] \text{?} - ∇ \text{?} [ \frac{k}{\text{?}} ∇ \text{?} ] = 0 \qquad ( 37 )$$

$$\text{?} \text{indicates text missing or illegible when filed}$$

To describe the heat flow, a law similar to that used for fluid flow is used, as seen previously. The heat flow q_{T} is obtained by the relationship between thermal conductivity and temperature gradient and indicates the heat flow that passes through an infinitesimal element.

$$q \text{?} = - k ∇ T \qquad ( 38 )$$

$$\text{?} \text{indicates text missing or illegible when filed}$$

Where k represents the thermal conductivity tensor and ∇T the thermal gradient. The negative sign in the equation indicates that the heat flow occurs from the region of higher temperature to the region with lower temperature. The heat conduction equation, in its turn, is written as:

$$- q \text{?} + Q = ρ cT \text{?} \qquad ( 39 )$$

$$\text{?} \text{indicates text missing or illegible when filed}$$

Where ρ is the mass density, c the specific heat, Q the rate of internal heat generated per unit volume, source term, and \dot{T} the temporal variation of temperature. Substituting the heat flow equation into the heat conduction equation, a new equation is obtained that governs the heat flow problem in terms of temperature:

$$k ∇ T = ρ cT \text{?} - Q \qquad ( 40 )$$

$$\text{?} \text{indicates text missing or illegible when filed}$$

In this equation, the material parameters are spatial functions and the source term contains the components of imposed heat flow and radiogenic heat, for example. The description of the generation of radiogenic heat for a depth l can be done using an exponential law as follows:

$$\text{?} \qquad ( 41 )$$

$$\text{?} \text{indicates text missing or illegible when filed}$$

A₀ is the radiogenic heat generated per unit volume of the rock, aᵣ is the radioactive decay constant, in units of length.

In order to deal with the condition in which one wishes to r thermo-fluid-mechanical effects together, it is necessary to define the conditions for these physical effects to be simulated. Thus, the energy conservation equation for both the solid and fluid media is shown below. The first assumption concerns the physical invariance of the fluid, that is, the fluid contained in the porous medium is in the liquid state and remains so, without changing phase. From this hypothesis, the energy conservation equation is derived without considering viscous dissipation, describing it for the fluid phase.

$$ρ \text{?} c \text{?} ϕ \text{?} ( T \text{?} + \text{?} ∇ T \text{?} ) = - ∇ ϕ J \text{?} - T \text{?} ( \frac{\partial p}{\partial T \text{?}} ) ϕ ∇ v \text{?} \qquad ( 42 )$$

$$\text{?} \text{indicates text missing or illegible when filed}$$

where C_{vf} is the specific heat and J is the heat flow by conduction. The same consideration adopted for a continuous medium was assumed to obtain the equation above. In the energy conservation equation, the first term on the left of the equality expresses the time dependence of the energy, the second term describes the variation of the energy due to convection. On the right side of the equality, there is the variation of the energy by conduction described in the first term and the variation of the energy due to the deformation of the porous medium in the second term.

Similarly, the conservation of energy for the solid phase can be described as

$$( 1 - ϕ ) ρ \text{?} c \text{?} ( T \text{?} + \text{?} ∇ T \text{?} ) = - ( 1 - ϕ ) ∇ J \text{?} - ( 1 - ϕ ) β T \text{?} ( \frac{\partial ε \text{?}}{\partial t} ) \qquad ( 43 )$$

$$\text{?} \text{indicates text missing or illegible when filed}$$

In the equation above β=(3λ+2μ)α, where α_{T} is the coefficient of thermal expansion and λ and μ are the Lame constants. As described in the energy conservation equation for the fluid phase, in the energy conservation equation for the solid phase, there is, in the second term on the right of the equality, the variation of energy caused by deformation.

Another important factor for the sequence of definitions concerns the concept of average temperature. At any point, the fluid, the solid and the porous medium as a whole are subject to the same average temperature. This consideration is based on the hypothesis that the flow channels of the porous medium are large in relation to the grains of the solid and that temperature equilibrium is obtained instantaneously when compared to other transport processes that occur in the domain. Thus, under this condition, the energy conservation equations for the fluid and solid medium can be combined in order to obtain the energy conservation equation for the porous medium.

$$[ ϕρ \text{?} c \text{?} ( 1 - ϕ ) ρ \text{?} c \text{?} ] T \text{?} + [ ϕρ \text{?} c \text{?} + ( 1 - ϕ ) ρ \text{?} c \text{?} ] ∇ T = - ∇ [ ( 1 - ϕ ) J \text{?} ] - T ( \frac{\partial p}{\partial T} ) ϕ ∇ v \text{?} - ( 1 - ϕ ) β T \text{?} ( \frac{\partial ε \text{?}}{\partial t} ) \qquad ( 44 )$$

$$\text{?} \text{indicates text missing or illegible when filed}$$

Assuming the law of Fourier for heat conduction is valid, it is possible to define:

$$J \text{?} = - λ \text{?} ∇ T \qquad ( 45 )$$

$$J \text{?} = - λ \text{?} ∇ T \qquad ( 46 )$$

$$\text{?} \text{indicates text missing or illegible when filed}$$

λₛ and λ_{f} are the thermal conductivity tensors.

If the solid phase velocity is disregarded, by rearranging some terms, the energy conservation equation can be rewritten as follows:

$$( ρ c \text{?} ) \text{?} T \text{?} [ ϕρ \text{?} c \text{?} v \text{?} ∇ T - ∇ \text{?} ( Λ \text{?} ∇ T ) + T ( \frac{\partial p}{\partial T} ) ϕ ∇ v \text{?} + ( 1 - ϕ ) β T \text{?} ( \frac{\partial ε}{\partial t} ) \qquad ( 47 )$$

$$Where {( ρ {c}_{v} )}_{m} = {ϕρ}_{f} {C}_{vf} + ( 1 - ϕ ) {ρ}_{s} {C}_{vs} and Λ \text{?} = ϕλ \text{?} + ( 1 - ϕ ) λ \text{?}$$

$$\text{?} \text{indicates text missing or illegible when filed}$$

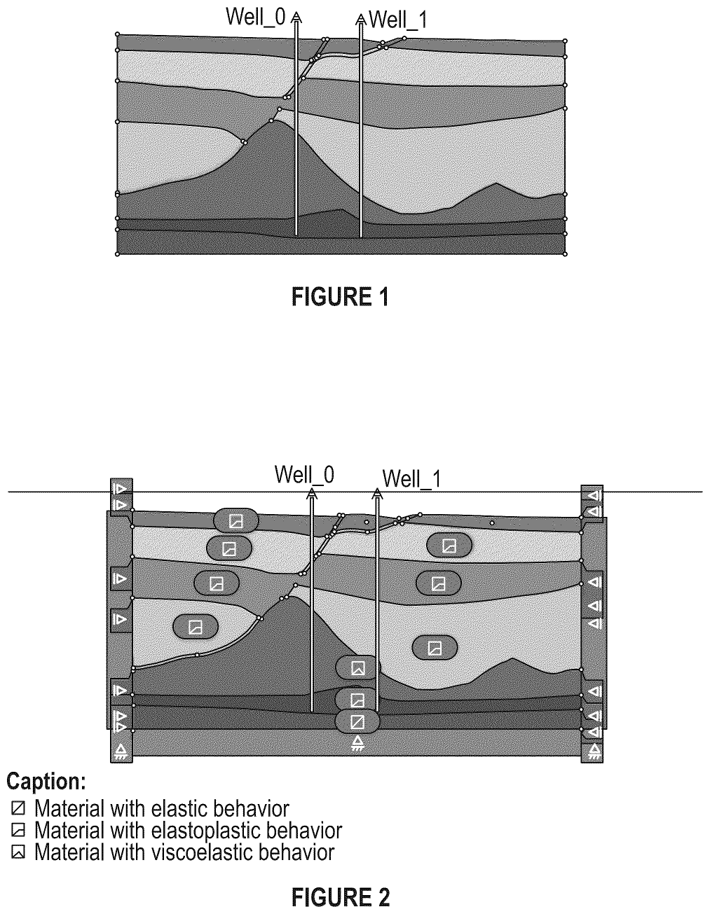

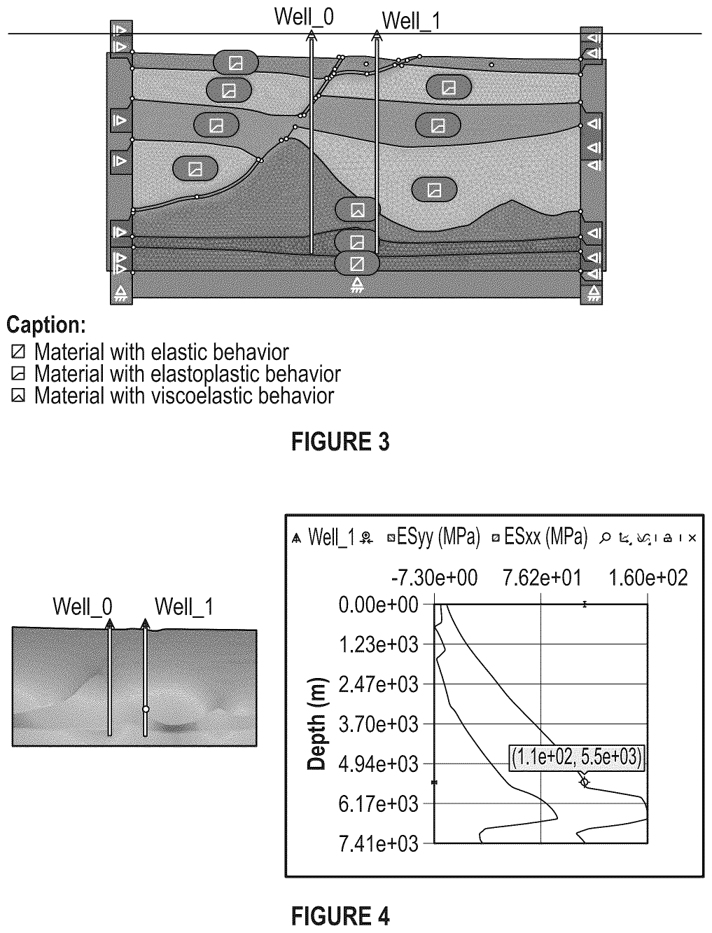

Basin-scale models for simulation are constructed based on the above equations and coupling combinations. The tectonic effects are modeled according to the types of loads, initial conditions in terms of stresses or displacements, temperatures or pore pressures, previously applied to the model as boundary conditions. The consideration of different types of material rheologies and their complexities are described by the stress/strain constitutive relations or by quantities present in fluid flow or heat flow problems. These constitutive relations describe the characteristics of the materials and their effects are taken into account in the solution of the equations indicated above. To solve the equations indicated above, the invention uses the numerical finite element method. The analysis flow for the basin scale is as follows: (a) description of the simulation project; and (b) definition of the geometry of the model, as seen in FIG. 1; (c) definition of the types of physical couplings used in the simulation; and (d) definition of the materials (geomechanical attributes) that characterize the model, initial and boundary conditions, as seen in FIG. 2; (e) construction of the finite element mesh model, as seen in FIG. 3; (f) construction of the data structure to compose the input data for solving the equations described above; (g) solving the equations using the finite element method; (h) writing the results into a data structure; (i) displaying the results in a graphical post-processing interface, as seen in FIG. 4.

With the results on a basin scale, it is possible to measure fields of displacements, stresses, deformations, pore pressures, and temperatures. Based on these results, regions with anomalous fields of results (stress levels, fluid overpressures, temperature gradients) can be located when compared with lithostatic results. Likewise, regions with mechanical damage, such as those determined by plastic deformations, can be located.

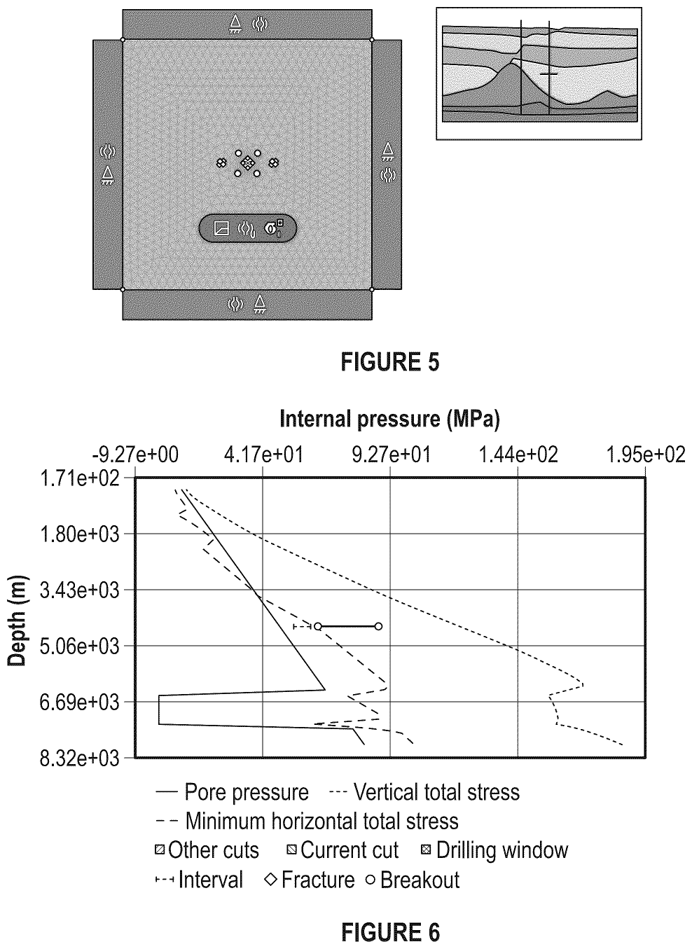

With the trajectory of oil wells in the basin scale model, the next phase of the analysis flow is entered. For any position along the trajectory of the well, a numerical simulation can be performed to evaluate the drilling stability window, that is, in step (b) the evaluation of the well stability window is performed in a model derived/extracted from step (a). The inputs for creating the well-scale model are collected in the basin-scale model by choosing a position/depth along the well trajectory, that is, in step (b.1) the position/depth at which a well-scale model is to be created is defined in the model created in (a). From this collection, the position of the well, the geomechanical properties and the initial stress state to be applied in the simulation are obtained. In addition, the creation of the geometry of the well section model requires some more information, namely: the diameter of the well and the lateral dimension of the well-scale model. If the well is directional, the inclination and azimuths must be informed. All data are provided via template, which allows adjusting the details of the model to the specificities of the real project in a simple way. After confirming the informed data, the method of the present invention automatically creates: a geometric model on the well scale with the informed dimensions, model length and well dimension; in addition to assigning all necessary boundary conditions, displacement restrictions, prescribed pore pressures, well wall loading; assigns the material properties of the rock formation; assigns the initial conditions in the formation (coming from the basin-scale model), initial stresses, initial pore pressures, initial temperature; creates the finite element mesh, with fine distribution around the well; defines the model as being a map view, as seen in FIG. 5.

For non-vertical directional wells, based on the direction and azimuth information, the initial stress fields will be automatically rotated to be compatible with the well direction.

After the well-scale geomechanical model creation stage, the parameters required for stability analysis are defined. The present invention works with two criteria, the shear criterion and the traction criterion, associated with a restriction of a maximum plasticized area and/or a maximum effective stress, which are determined according to the specificities of the well drilling project. The shear criterion quantifies the damage to the formation resulting from variations in stress levels and the consequent formation of regions with plastic deformations. Plastic deformations are an indication of a weakened region with the possibility of detachment and consequent generation of solids, leading to loss of well circumference, collapse, loss of equipment, among other possible problems. The traction criterion indicates the possibility of breaking the porous medium with possible loss of drilling fluid and consequent damage to the drilling process and equipment. It should be noted that, since this is a numerical problem with a parabolic solution, the application of each restriction (plasticized area or maximum effective stress) will result in two internal pressure values, representing the minimum and maximum limits of the solution range, that is, the stability window. Thus, it is understood that if the drilling pressure on the well wall is lower than the minimum or exceeds the maximum, there will be instability in the well drilling process. In addition, it should be noted that the plasticization area and/or the maximum effective stress level are defined arbitrarily, according to the well design specifications and the geological context of the region. Based on this information, the invention will determine the drilling pressure window automatically via optimization methods.

The optimization problem in the present invention seeks to determine what drilling pressure should be applied to the well wall to ensure the well stability conditions according to the two criteria indicated above. For this purpose, the minimization problem with constraints of two objective functions (functions to be minimized) is described.

Specifically, in step (b.3) an optimization process is performed applied to the geomechanical analysis at the well scale that uses the Accelerated Newton-Raphson method or the Aitken Accelerated False Position Method and the constraints shown in the following equations [48], [49] and [50]. In particular, the failure in the well can be represented as a function of the internal pressure by the following equations:

$${F}_{1} ( {P}_{w} ) = A ( {P}_{w} ) - {A}^{*} \qquad ( 48 )$$

For the maximum plasticization region criterion:

$${F}_{2} ( {P}_{w} ) = {σ}_{1} ( {P}_{w} ) - {σ}_{1}^{*} \qquad ( 49 )$$

In addition, the internal pressure must also be greater than the pore pressure of the medium and less than the lithostatic stress in the well, σ_{LIT}. Thus, the calculation of the limits of the stability window corresponds to:

$$min ou max {P}_{w} , tal que \{ \begin{matrix}{F}_{1} ( {P}_{w} ) \leq 0 \\ {F}_{2} ( {P}_{w} ) \leq 0 \\ p - {P}_{w} \leq 0 \\ {P}_{w} - {σ}_{LIT} \leq 0\end{matrix} \qquad ( 50 )$$

The lower limit of the window is characterized by the largest of the roots of the constraints that minimize the internal pressure and the upper limit is calculated from the smallest of the roots that maximizes the internal pressure. For the conditions of maximum plasticized area and maximum effective tensile stress allowed, the roots are calculated with the Accelerated Newton-Raphson methods, and with the Aitken Accelerated False Position Method.

After the calculation process, the results of the invention can be presented to the user representing the drilling pressure range that can be used to drill the well safely, according to the established criteria, as seen in FIG. 6.

The present invention also relates to a non-transitory computer-readable storage medium comprising instructions stored therein, wherein the instructions, when read by a computer, cause the computer to execute the steps of the method as previously defined.

1. A computer-implemented method for multiscale analysis to define stability windows for oil wells, comprising the steps of:
(a) performing geomechanical analysis on a basin scale model, comprising:
(a.1) creating a geometric model, on a basin scale, representing a geological context wherein a well is inserted;
(a.2) assigning to the model geomechanical properties and boundary conditions characteristic of the geological context;
(a.3) discretizing the model through a finite element mesh;
(a.4) performing a geomechanical analysis;
(a.5) displaying results for stress and strain fields; and
(b) performing an evaluation of a well stability window in a model derived and/or extracted from step (a), comprising:
(b.1) creating a geometric model and assigning the geomechanical properties and boundary conditions via template;
(b.2) discretizing through a finite element mesh automatically;
(b.3) performing a mathematical optimization process related to the geomechanical analysis on a well scale;
(b.4) presenting a final result in a graph representing a well trajectory with an indication of the well stability window obtained.

2. The method of claim 1, wherein the step (a.4) comprises using equations [1] to [47].

3. The method of claim 1, wherein the step (b.3) obtains the well stability window for an internal pressure of a wellbore by the Accelerated Newton-Raphson method or the False Position Method with Aitken Acceleration with restrictions presented in equations [48], [49], and [50].

4. The method of claim 1, wherein the step (b.1) complements the template with geometric data of a wellbore such as diameter, azimuth, and inclination.

5. A non-transitory computer-readable storage medium comprising instructions stored therein, wherein the instructions, when read by a computer, cause the computer to perform the steps of the method claim 1.
